(19) United States
(12) Patent Application Publication
(10) Pub. No.: US 2018/0086876 A1
(43) Pub. Date: Mar. 29, 2018

(54) THERMOSETTING RESIN COMPOSITION, ELECTRONIC PART, ELECTRIC MACHINE COIL, ELECTRIC MACHINE, AND CABLE

(71) Applicant: HITACHI, LTD., Tokyo (JP)

(72) Inventors: Yasuhiko TADA, Tokyo (JP); Takahito MURAKI, Tokyo (JP); Yuri KAJIHARA, Tokyo (JP)

(73) Assignee: HITACHI, LTD., Tokyo (JP)

(21) Appl. No.: 15/540,692

(22) PCT Filed: Jan. 26, 2015
(86) PCT No.: PCT/JP2015/051954

§ 371 Date: Jun. 29, 2017

(51) Int. Cl. C08G 59/68; G03F 7/20; G03F 7/039; G03F 7/40; H01L 21/027

(52) U.S. Cl. CPC C08G 59/68; G03F 7/2024; H01L 21/027; G03F 7/40; G03F 7/039

(57) ABSTRACT

It is an object of the present invention to provide a thermosetting resin composition which allows stress relaxation in an ester exchange reaction and the long-term use of the thermosetting resin composition having such a structure. A thermosetting resin composition of the present invention contains: an ester bond; and a functional group protected by a protecting group. The functional group is deprotected by external stimulus. The functional group and the ester bond can be subjected to an ester exchange reaction.

### TECHNICAL FIELD

The present invention relates to a thermosetting resin composition.

### BACKGROUND ART

A rotating machine such as a motor, an electric machine coil such as a static apparatus (such as a transformer), and a power device used in a power electronics machine are coated with a thermosetting resin composition for the purpose of electric insulation, heat release during operation, absorption of beat generated by electric vibration, and bonding of constituting materials, or the like. As the thermosetting resin material capable of exhibiting the above functions, an unsaturated polyester resin and an epoxy resin or the like have mainly been used.

However, since the thermosetting resin composition used for the coating treatment has a bonded surface between different materials such as between a coil and a resin, strain caused by the difference between the expansion coefficients of the materials causes cracks and peelings when a temperature change causes the thermal expansions and contractions of the materials, which may cause deterioration in the reliability of the machine. Therefore, a thermosetting resin composition having high durability is required.

In order to match the coefficient of thermal expansion of a cured product made of a thermosetting resin composition and the coefficient of thermal expansion of the different material to each other, this problem is solved by a method including mixing a thermosetting resin composition with a ceramic filler such as silica to adjust the coefficient of thermal expansion (PTLs 1 and 2). However, when the filler is added, the viscosity of the thermosetting resin composition is increased, and the impregnating property of the thermosetting resin composition is deteriorated, as a result of which an unfilled region is present. Furthermore, a method using a thermosetting resin composition under high vacuum to improve the impregnating property of the thermosetting resin composition is considered, which disadvantageously causes the formation of vacuum voids in a resin.

On the other hand, in recent years, a resin composition using a dynamic covalent bond draws increasing attention. The dynamic covalent bond is a covalent bond allowing reversible dissociation-bond under external stimulus such as heat or light, and the bond is trially included in the network structure of a resin. Since the cured product has a network structure changed by the dynamic covalent bond, stress such as strain occurring in the cured product is expected to be relaxed to suppress cracks.

An example using the dynamic covalent bond for the thermosetting resin composition is NPL 1. The dynamic covalent bond of an ester exchange reaction is introduced into an obtained cured product by using a bisphenol A type monomer and a carboxylic acid or a carboxylic anhydride as a curing agent, and a zinc complex as a catalyst, to achieve the stress relaxation of the cured product.

However, a hydroxyl group involved in the ester exchange reaction receives contamination such as water molecule or an organic matter in the atmosphere, or causes a side reaction at high temperatures, as a result of which the ester exchange reaction may not function. The usage environment is not considered.

### CITATION LIST

### Patent Literature

PTL 1: Japanese Patent Application Laid-Open No. 62-224009
PTL 2: Japanese Patent Application Laid-Open No. 2-32508

### SUMMARY OF INVENTION

### Technical Problem

In order to solve the problem in the above situation, it is an object of the present invention to provide a thermosetting resin composition allowing stress relaxation in an ester exchange reaction and the long-term use of the thermosetting resin composition having such a structure.

### Solution to Problem

A thermosetting resin composition of the present invention contains: an ester bond; and a functional group protected by a protecting group. The functional group is deprotected by external stimulus. The functional group and the ester bond can be subjected to an ester exchange reaction.

### Advantageous Effects of Invention

The present invention allows stress relaxation to suppress crack occurrence, thereby providing a thermosetting resin composition capable of being used for a long time.

### BRIEF DESCRIPTION OF DRAWINGS

FIG. 1 is a perspective view of an electronic package including a thermosetting resin composition of the present invention as a mold sealant.

FIG. 2 is a sectional view of the electronic package including the thermosetting resin composition of the present invention as the mold sealant.

FIG. 3 is an upper side view of a motor including the thermosetting resin composition of the present invention as a motor coil protective material.

FIG. 4 is a sectional view of the motor including the thermosetting resin composition of the present invention as the motor coil protective material.

FIG. 5 is a sectional view (1) of a cable manufactured using the thermosetting resin composition of the present invention.

FIG. 6 is a sectional view (2) of the cable manufactured using the thermosetting resin composition of the present invention.

### DESCRIPTION OF EMBODIMENTS

Hereinafter, an embodiment of a thermosetting resin composition of the present invention will be appropriately described in detail with reference to the drawings. Since the thermosetting resin composition contains an ester bond and a catalyst required for an ester exchange reaction, the thermosetting resin composition allows stress relaxation due to a change in a network structure. A hydroxyl group involved in the ester exchange reaction is protected by a protecting group, and the protecting group is deprotected by external stimulus if needed, to develop the ester exchange reaction.

Hereinafter, the thermosetting resin composition, and an electronic part and an electric machine which include the thermosetting resin composition will be described.

<Method for Producing Thermosetting Resin Composition>

The thermosetting resin composition of the present invention has a different proper curing temperature region depending on a curing agent and a catalyst, and is obtained by heating a mixture containing a monomer forming an ester bond during curing, a monomer having a structure containing an ester bond as a monomer skeleton and capable of forming a cross-linked structure, a mixture of both the monomers, or a monomer containing a hydroxyl group (formula 1) protected by a protecting group and capable of forming a cross-linked structure with an ester bond or other monomer during curing, a curing agent, and a catalyst at 80 to 200° C.

A curing time and a curing temperature are appropriately adjusted depending on the intended use. The thermosetting resin composition obtained after curing contains an ester bond, a hydroxyl group, and a catalyst promoting an ester exchange reaction. The ester exchange reaction appropriately occurs, and thereby the thermosetting resin composition contains a covalent bond allowing reversible dissociation-bond. The chemical formula of the ester exchange reaction is shown as Formula 2. The chemical formula shown in Formula 2 is a part of a structure obtained in the ester exchange reaction.

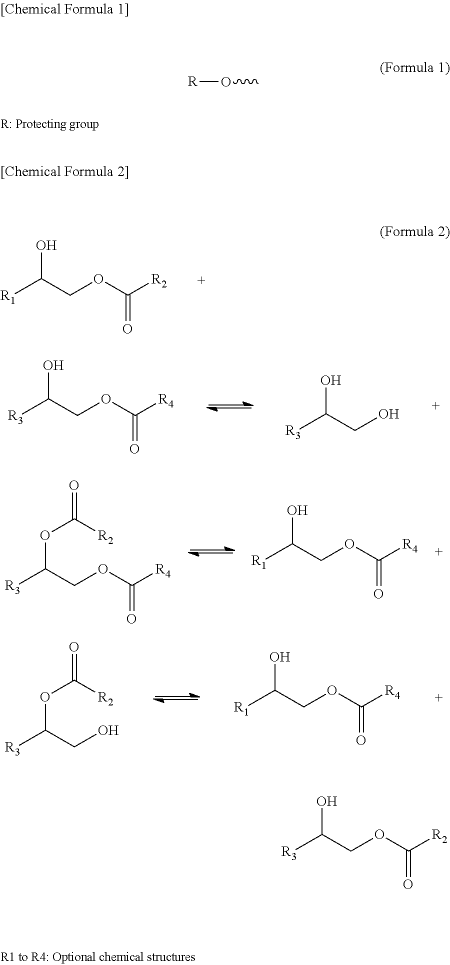

<Monomer and Curing Agent>

The resin composition of the present invention desirably has a structure containing a monomer forming an ester bond during curing or an ester bond as a monomer skeleton. The monomer forming an ester bond during curing preferably contains an epoxy compound having a multifunctional epoxy group, and a carboxylic anhydride or a polyvalent carboxylic acid as a curing agent. Furthermore, the epoxy compound is preferably a bisphenol A type resin, a novolac type resin, an alicyclic resin, or a glycidyl amine resin.

Examples of the epoxy include, but are not limited to, bisphenol A diglycidyl ether phenol, bisphenol F diglycidyl ether, bisphenol S diglycidyl ether, resorcinol diglycidyl ether, hexahydro bisphenol A diglycidyl ether, polypropylene glycol diglycidyl ether, neopentyl glycol diglycidyl ether, phthalic acid diglycidyl ester, dimer acid diglycidyl ester, triglycidyl isocyanurate, tetraglycidyl diamino diphenyl methane, tetraglycidyl methaxylene diamine, cresol novolac polyglycidyl ether, tetrabrome bisphenol A diglycidyl ether, and bisphenol hexafluoroacetone diglycidyl ether.

Examples of the carboxylic anhydride or the polyvalent carboxylic acid as the curing agent include, but are not limited to, phthalic anhydride, tetrahydrophthalic anhydride, hexahydrophthalic anhydride, methyltetrahydrophthalic anhydride, 3-dodecenyl succinic anhydride, octenyl succinic anhydride, methylhexahydrophthalic anhydride, methylnadic anhydride, dodecyl succinic anhydride, chlorendic anhydride, pyromellitic anhydride, benzophenonetetracarboxylic anhydride, ethyleneglycol bis(anhydrotrimate), methylcyclohexene-tetracarboxylic anhydride, trimellitic anhydride, polyazelaic anhydride, ethylene glycol bisanhydrotrimellitate, 1,2,3,4-butanetetracarboxylic acid, 4-cyclohexene-1,2-dicarboxylic acid, and polyvalent fatty acid.

<Hydroxyl Group Containing Protecting Group in Resin Composition>

It is preferable that a hydroxyl group containing a protecting group in the resin composition is previously mixed with a compound containing a hydroxyl group protected by a protecting group during curing. The compound containing the hydroxyl group protected by the protecting group is preferably a compound containing a hydroxyl group formed by ring-opening some epoxy groups before curing among the epoxy compounds and protected by a protecting group. The protecting group is deprotected by external stimulus, to form a hydroxyl group [Chemical Formula 3]. Examples of the external stimulus include, but are not limited to, heat and light.

When the external stimulus is the heat, the hydroxyl group is deprotected by heat having a temperature of 140 to 200° C. When the external stimulus is the light, the resin composition preferably contains a photo-acid-generating agent generating an acid under light stimulus.

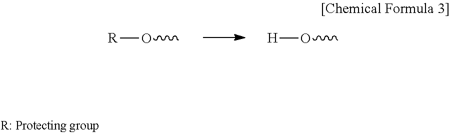

Examples of the protecting group include, but are not limited to, trichloroacetate ester, formate ester, acetate ester, isobutyrate, pivalate ester, benzoic ester, methoxymethyl ether, tetrahydropyranyl ether, tetrahydrothiopyranyl ether, 4-methoxy tetrahydropyranyl ether, 4-methoxy tetrahydrothiopyranyl ether, tetrahydrofuranyl ether, tetrahydrothiofuranyl ether, 1-methyl-1-methoxyethylether, 2-(phenylseleninyl)ethylether, t-butyl ether, allyl ether, benzyl ether, o-nitrobenzyl ether, triphenylmethyl ether, and a-naphthyl diphenyl methyl ether.

<Catalyst>

It is preferable that the catalyst is uniformly dispersed in a mixture, and promotes an ester exchange reaction. Examples thereof include, but are not limited to, zinc acetate (II), zinc (II) acetylacetonato, zinc naphthenate (II), iron acetylacetonate (III), cobalt acetylacetonate (II), cobalt acetylacetonate (III), aluminum isopropoxide, titanium isopropoxide, a methoxide(triphenylphosphine)copper (I) complex, an ethoxide(triphenylphosphine)copper (I) complex, a propoxide(triphenylphosphine)copper (I) complex, an isopropoxide(triphenylphosphine)copper (I) complex, a methoxidebis(triphenylphosphine)copper (II) complex, an ethoxidebis(triphenylphosphine)copper (II) complex, a propoxide bis(triphenylphosphine)copper (II) complex, an isopropoxide bis(triphenylphosphine)copper (II) complex, tris(2,4-pentanedionato)cobalt (III), cobalt naphthenate (II), cobalt stearate (II), tin diacetate (II), di(2-ethylhexanoate)tin (II), N,N-dimethyl-4-aminopyridine, diazabicycloundecene, diazabicyclononene, triazabicyclodecene, triphenylphosphine, 2-phenylimidazole, 2-phenyl-4-methylimidazole, 1-benzyl-2-phenylimidazole, and 1-cyanoethyl-2-phenylimidazole.

### EXAMPLES

Next, the present invention will be more specifically described while Examples are shown.

### Example 1

To a mixture (jER828/epoxy compound, molar ratio: 1/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-2200 3 or 4-methyl-1,2,3,6-tetrahydrophthalic anhydride (Hitachi Chemical Co., Ltd.) and 0.01 molar equivalence of zinc (II) acetylacetonato were added, followed by stirring and mixing in the atmosphere, to obtain a mixture. The mixture was then cast into a 2-mm-thick plate-like mold, and heated at 120° C. for 12 hours, to cure the mixture. The hydroxyl group of bisphenol A bis(2,3-dihydroxypropyl)ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction even after the exposure test was confirmed.

### Example 2

To a mixture (jER828/epoxy compound, molar ratio: 3/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-2200 3 or 4-methyl-1,2,3,6-tetrahydrophthalic anhydride (Hitachi Chemical Co., Ltd.) and 0.01 molar equivalence of zinc (II) acetylacetonato were added, followed by stirring and mixing in the atmosphere, to obtain a mixture. The mixture was then cast into a 2-mm-thick plate-like mold, and heated at 120° C. for 12 hours, to cure the mixture. The hydroxyl group of bisphenol A bis(2,3-dihydroxypropyl)ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction even after the exposure test was confirmed.

### Example 3

To a mixture (jER828/epoxy compound, molar ratio: 19/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-2200 3 or 4-methyl-1,2,3,6-tetrahydrophthalic anhydride (Hitachi Chemical Co., Ltd.) and 0.01 molar equivalence of zinc (II) acetylacetonato were added, followed by stirring and mixing in the atmosphere, to obtain a mixture. The mixture was then cast into a 2-mm-thick plate-like mold, and heated at 120° C. for 12 hours, to cure the mixture. The hydroxyl group of bisphenol A bis(2,3-dihydroxypropyl)ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction even after the exposure test was confirmed.

### Example 4

To a mixture (jER828/epoxy compound, molar ratio: 1/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-5500 methyl-hexahydrophthalic anhydride (Hitachi Chemical Co., Ltd.) and 0.01 molar equivalence of zinc acetate were added, followed by stirring and mixing at about 100° C., to obtain a mixture. The mixture was then cast into a 2-mm-thick plate-like mold, and heated at 120° C. for 12 hours, to cure the mixture. The hydroxyl group of bisphenol A bis (2,3-dihydroxypropyl) ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction even after the exposure test was confirmed.

### Example 5

To a mixture (jER828/epoxy compound, molar ratio: 19/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-2200 (Hitachi Chemical Co., Ltd.) and 0.01 molar equivalence of 1-benzyl-2-phenylimidazole were added, followed by stirring and mixing in the atmosphere, to obtain a mixture. The mixture was then cast into a 2-mm-thick plate-like mold, and heated at 120° C. for 12 hours, to cure the mixture. The hydroxyl group of bisphenol Abis (2,3-dihydroxypropyl) ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction even after the exposure test was confirmed.

### Comparative Example 1

To a mixture (jER828/epoxy compound, molar ratio: 39/1) of a jER828 epoxy resin (Mitsubishi Chemical) and an epoxy compound obtained by protecting a hydroxyl group of bisphenol A bis(2,3-dihydroxypropyl)ether by trichloroacetate ester, 1.0 molar equivalence of HN-2200 (Hitachi Chemical Co., Ltd.) and 0.01 molar equivalence of zinc (II) acetylacetonato were added, followed by stirring and mixing at about 100° C., to obtain a mixture. The mixture was then cast into a 2-mm-thick plate-like mold, and heated at 120° C. for 12 hours, to cure the mixture. The hydroxyl group of bisphenol A bis(2,3-dihydroxypropyl)ether was protected by reacting trichloroacetic acid chloride in the presence of a base.

Then, the cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading. As a result, in the test pieces produced in the present Example, the progression of the ester exchange reaction after the exposure test was not confirmed.

### Comparative Example 2

To a jER828 epoxy resin (Mitsubishi Chemical), 1.0 molar equivalence of HN-2200 methy-hexahydrophthalic anhydride (Hitachi Chemical Co., Ltd.) and 0.01 molar equivalence of zinc (II) acetylacetonato were added, followed by stirring and mixing in the atmosphere, to obtain a mixture. The mixture was then cast into a 2-mm-thick plate-like mold, and heated at 120° C. for 12 hours, to cure the mixture.

The cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 2200 hours, the existence or non-existence of an ester exchange reaction was confirmed by a creep test. The creep test was carried out while predetermined stress of 0.2 MPa was loaded on the test pieces at 150° C. In all the five test pieces, the ester exchange reaction was determined to progress when strain after unloading was greater than that before loading. As a result, in the test pieces produced in the present Example, the progression of the ester exchange reaction after the exposure test was not confirmed.

### Comparative Example 3

To a jER828 epoxy resin (Mitsubishi Chemical), 1.0 molar equivalence of HN-2200 methy-hexahydrophthalic anhydride (Hitachi Chemical Co., Ltd.) and 0.01 molar equivalence of 1-benzyl-2-phenylimidazole were added, followed by stirring and mixing in the atmosphere, to obtain a mixture. The mixture was then cast into a 2-mm-thick plate-like mold, and heated at 120° C. for 12 hours, to cure the mixture. The cured resin composition was processed into a test piece suitable for a tensile test. The test piece had a No. 1 type test piece shape according to the specification described in JIS K 7161. Five test pieces were produced.

After the produced test pieces were exposed under a high temperature and high humidity environment of 85° C. and 85% for 1500 hours, the existence or non-existence of an ester exchange reaction was confirmed by a creep test. The creep test was carried out while predetermined stress of 0.2 MPa was loaded on the test pieces at 200° C. In all the five test pieces, the ester exchange reaction was determined to progress when strain after unloading was greater than that before loading.

As a result, in the test pieces produced in the present Comparative Example, the progression of the ester exchange reaction after the exposure test was not confirmed.

<Consideration of Examples 1 to 5 and Comparative Examples 1 to 3>

Data obtained in Examples 1 to 5 and Comparative Examples 1 to 3 are shown in Table 1. jER828 epoxy resin/epoxy compound (molar ratio) of each of Examples 1 to 5 and Comparative Examples 1 to 3 is as follows. The molar ratios are 1/1 in Example 1, 3/1 in Example 2, 19/1 in Example 3, 1/1 in Example 4, 19/1 in Example 5, 39/1 in Comparative Example 1, 1/0 in Example 2, and 1/0 in Example 3.

The ratio can be expressed as the percentage of the hydroxyl groups protected by the protecting group among the hydroxyl groups contained in the whole resin composition. The percentages are 100% in Example 1, 50% in Example 2, 10% in Example 3, 100% in Example 4, 50% in Example 5, 100% in Comparative Example 1, 0% in Comparative Example 2, and 0% in Comparative Example 3.

The progression of the ester exchange reaction after the exposure test was confirmed in Examples 1 to 5, but the progression of the ester exchange reaction after the exposure test was not confirmed in Comparative Examples 1 to 3. Therefore, it was found that the percentage of the hydroxyl groups protected by the protecting group among the hydroxyl groups contained in the whole resin composition was required to be 10% or more in order to allow the progression of the ester exchange reaction.

TABLE 1

| | Example 1 | Example 2 | Example 3 | Example 4 | Example 5 |
|---|---|---|---|---|---|
| Ester bond | jER828 epoxy resin | jER828 epoxy resin | jER828 epoxy resin | jER828 epoxy resin | jER828 epoxy resin |
| Protecting group | Trichloroacetate ester | Trichloroacetate ester | Trichloroacetate ester | Trichloroacetate ester | Trichloroacetate ester |
| Functional group protected by | Hydroxyl group of | Hydroxyl group of | Hydroxyl group of | Hydroxyl group of | Hydroxyl group of |
| protecting group | bisphenol A | bisphenol A | bisphenol A | bisphenol A | bisphenol A |
| | bis(2,3-dihy- | bis(2,3-dihy- | bis(2,3-dihy- | bis(2,3-dihy- | bis(2,3-dihy- |
| | droxypropyl)ether | droxypropyl)ether | droxypropyl)ether | droxypropyl)ether | droxypropyl)ether |
| jER828 epoxy resin/epoxy | 1/1 | 3/1 | 19/1 | 1/1 | 19/1 |
| compound (molar ratio) | | | | | |
| Curing agent | HN2200 | HN2200 | HN2200 | HN5500 | HN2200 |
| Catalyst | Zinc (II) | Zinc (II) | Zinc (II) | Zinc acetate | 1-benzyl-2-phe- |
| | acetylacetonato | acetylacetonato | acetylacetonato | | nylimidazole |
| Percentage of protected | 100% | 50% | 10% | 100% | 10% |
| hydroxyl groups in | | | | | |
| all hydroxyl groups | | | | | |
| Progression of ester | Existence | Existence | Existence | Existence | Existence |
| exchange reaction | | | | | |

| | Comparative Example 1 | Comparative Example 2 | Comparative Example 3 |
|---|---|---|---|
| Ester bond | jER828 epoxy resin | jER828 epoxy resin | jER828 epoxy resin |
| Protecting group | Trichloroacetate ester | Non-existence | Non-existence |
| Functional group protected by | Hydroxyl group of | Non-existence | Non-existence |
| protecting group | bisphenol A | | |
| | bis(2,3-dihy- | | |
| | droxypropyl)ether | | |
| jER828 epoxy resin/epoxy | 39/1 | 1/0 | 1/0 |
| compound (molar ratio) | | | |
| Curing agent | HN2200 | HN2200 | HN2200 |
| Catalyst | Zinc (II) | Zinc (II) | 1-benzyl-2-phe- |
| | acetylacetonato | acetylacetonato | nylimidazole |
| Percentage of protected | 5% | 0% | 0% |
| hydroxyl groups in | | | |
| all hydroxyl groups | | | |
| Progression of ester | Non-existence | Non-existence | Non-existence |
| exchange reaction | | | |

### Example 6

<Mold Sealant>

The thermosetting resin composition of the present invention can be used for a mold sealant, a potting material used for the manufacture of a mold sealant (potting material for manufacturing a mold sealant), and an electronic part package or the like.

Mold sealing has problematic formability. This is intricately related to many factors such as a packaging structure, a mold, a sealant, and a molding technique. Specifically, residual strain or warping deformation occurs from the difference in the cure shrinkage of the resin, and the physical properties of a heat release substrate, a resin, and a silicon chip or the like as constitutional materials. This causes the property fluctuation, cracks, and peelings of the chip, or the like.

When the thermosetting resin composition of the present invention is applied as the mold sealant for the problem, the residual strain after curing can be reduced by the exchange reaction of a dynamic covalent bond region, which can suppress the occurrence of the cracks and the peelings.

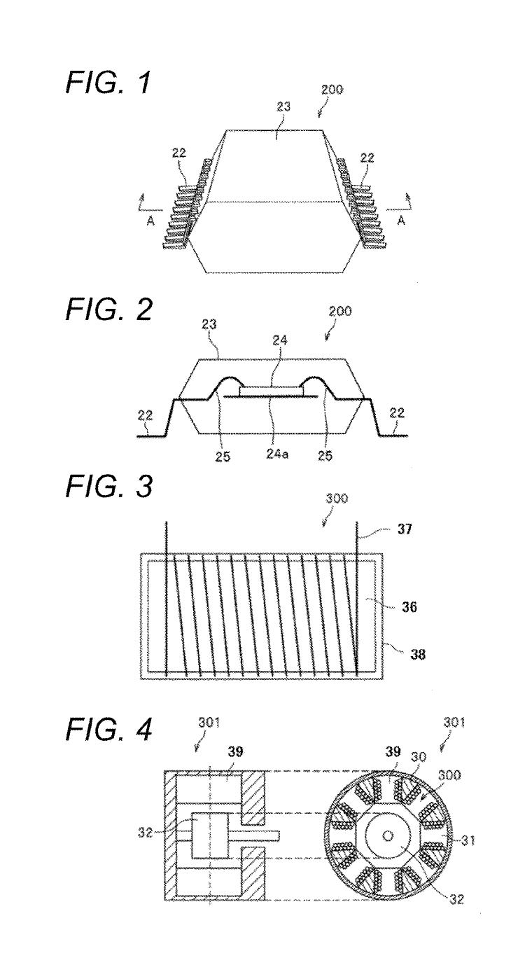

FIGS. 1 and 2 shows an electronic package including the thermosetting resin composition of the present invention as the mold sealant. FIG. 1 is a perspective view of the electronic package, and FIG. 2 is an A-A sectional view of the electronic package of FIG. 1.

An electronic package 200 includes a semiconductor device 24 disposed on a substrate 24a, lead frames 22 extending outward of a mold sealant 23, and bonding wires 25 for electrically connecting the lead frames 22 and the semiconductor device 24. The lead frames 22, the semiconductor device 24, the substrate 24a, and the bonding wires 25 are sealed by a mold sealant made of a dynamically cross-linked resin of the present invention.

Both the lead frames 22 and the bonding wires 25 are formed of a good conductor, and are specifically made of copper, aluminum, or the like. The form of the lead frames 22 and the bonding wires 25 can be in any known form, for example, solid wires or twisted wires.

As the shape of the semiconductor device 24, for example, a circular shape, a divided circular shape, and a compression shape or the like can be applied. Furthermore, the material for constituting the semiconductor device 24 is not particularly limited so long as this is a material which can be sealed by the mold sealant 23.

After the mold sealant 23 obtained in the present Example was exposed was exposed under a high temperature and high humidity environment of 85° C. and 85% for 2200 hours, a temperature cycle test (−50° C. to 150° C.) was carried out. Cracks and peelings or the like did not occur in the mold sealant 23.

### Example 7

<Motor Coil Insulating Material>The thermosetting resin composition of the present invention can be applied as a motor coil protective material and a motor coil varnish. An electric machine coil such as a motor is processed with a thermosetting resin composition with the aim of electrical insulation, heat release during operation, the absorption of a beat note caused by electrical vibration, and the fixation of a constituent material, or the like. It is important that the cracks do not occur in a fixed part between the resin and the coil during the electrical vibration under the condition of the heat release during operation.

Then, examples of properties required for the resin include long-term heat resistance, long-term strength, and flexibility or plasticity freely responding to the thermal expansion of a coil made of a metal.

In the thermosetting resin composition of the present invention, the exchange reaction of a dynamic covalent bond part occurs under the heat release condition, which responds to the expansion of the metal. This causes the deformation of the resin composition, which can suppress cracks.

FIGS. 3 and 4 show a motor including the thermosetting resin composition of the present invention as a motor coil protective material. FIG. 3 is an upper side view of a coil 300; FIG. 4 shows a sectional structure of a motor 301 including the coil 300; FIG. 4 is a sectional view in a direction parallel to the axial direction of a rotor magnetic core 32 on a left side; and FIG. 4 is a sectional view in a direction perpendicular to the axial direction of the rotor magnetic core 32 on a right side.

The motor coil 300 includes a magnetic core 36, a coated copper wires 37 wound around the magnetic core 36, and a motor coil protective material 38 made of the thermosetting resin composition of the present invention. The coil 300 is uniformly coated with the thermosetting resin composition of the present invention according to the present embodiment as a varnish material for the motor coil protective material.

The magnetic core 36 is made of a metal such as iron, or the like, for example. Furthermore, an enamel wire having a diameter of 1 mm is used as the coated copper wire 37.

The coil 300 is used for the motor 301 shown in FIG. 4. The motor 301 includes a cylindrical stator magnetic core 30 fixed to the inner edge part of the motor 301, a rotor magnetic core 32 rotated coaxially at the inside of the stator magnetic core 30, a stator coil 39, and eight coils 300 in which coated copper wires are wound in slots 31 of the stator magnetic core 30.

The coil 300 was prepared by winding an enameled wire having a diameter of 1 mm on a winding spool. This coil was dipped in the thermosetting resin composition shown in Example 1, and then cured at 120° C. for 0.5 hour to obtain the insulation-treated coil 300.

After the coil 300 obtained in the present Example was exposed under a high temperature and high humidity environment of 85° C. and 85% for 2200 hours, a temperature cycle test (−50° C. to 150° C.) was carried out. Cracks and peelings or the like did not occur in the fixed portion of the coil 300.

### Example 8

A stator including a coil prepared by winding an enameled wire having a diameter of 1 mm on a winding spool was dipped in the thermosetting resin composition shown in Example 1, and then cured at 120° C. for 0.5 hour to obtain the stator including the fixed coil.

After the stator obtained in the present Example was exposed under a high temperature and high humidity environment of 85° C. and 85% for 2200 hours, a temperature cycle test (−50° C. to 150° C.) was carried out. Cracks and peelings or the like did not occur in the fixed portion of the stator.

### Example 9

<Cable Covering Material>

The thermosetting resin composition of the present invention can be applied to a cable and a covering material. The resin used for the cable and the cable covering material must have resin strength and heat resistance. Damages may occur in the resin material such as occurrence of external damages during long-term use, scratching damages caused by friction between cables, and micro cracks caused by abrupt thermal change. When the thermosetting resin composition of the present invention is used under these circumstances, the damages and the scratching damages can be reduced by the exchange reaction of a dynamic covalent bond.

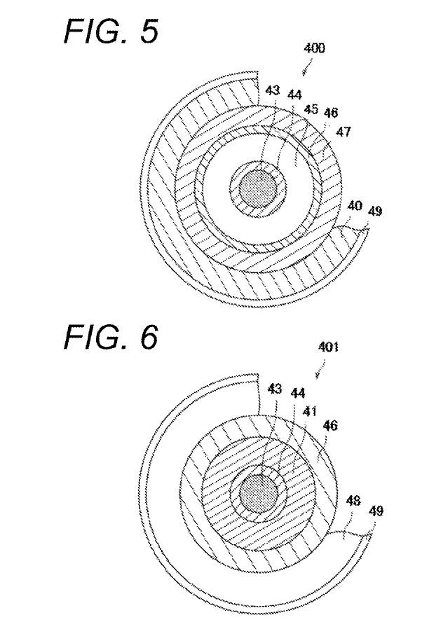

FIGS. 5 and 6 are sectional views of the cable manufactured using the thermosetting resin composition of the present invention. A cable 400 includes a covering layer 40, an insulating layer 41, a conductor 43, an internal semiconductor layer 44, an insulating layer 45, an external semiconductor layer (adhesion layer) 46, an external semiconductor layer (peeling layer) 47, a covering layer 48, and an outer coating layer 49.

After the cable and the cable covering material obtained in the present Example were exposed under a high temperature and high humidity environment of 85° C. and 85% for 2200 hours, a temperature cycle test (−50° C. to 150° C.) was carried out. Cracks and peelings or the like did not occur in the cable.

### REFERENCE SIGNS LIST

200 electronic package
22 lead frame
23 mold sealant
24 semiconductor device
24a substrate
25 bonding wire
300 coil
301 motor
30 stator magnetic core
31 slot
32 rotor magnetic core
36 magnetic core
37 coated copper wire
38 motor coil protective material
39 stator coil
400 cable
401 cable
40 covering layer
41 insulating layer
43 conductor
44 internal semiconductor layer
45 insulating layer
46 external semiconductor layer (adhesion layer)
47 external semiconductor layer (peeling layer)
48 covering layer
49 outer coating layer

1. A thermosetting resin composition comprising:
an ester bond; and
a functional group protected by a protecting group,
wherein the functional group is deprotected by external stimulus,
the functional group and the ester bond can be subjected to an ester exchange reaction, and
the functional group is a hydroxyl group formed by ring-opening some multifunctional epoxy groups of an epoxy compound containing multifunctional epoxy groups.

2. The thermosetting resin composition according to claim 1,
wherein the functional group is a hydroxyl group.

3. The thermosetting resin composition according to claim 2,
wherein the hydroxyl group is protected by the protecting group via an ether bond.

4. The thermosetting resin composition according to claim 2,
wherein a percentage of the hydroxyl groups protected by the protecting group to the hydroxyl groups contained in the whole thermosetting resin composition is 10% or more.

5. The thermosetting resin composition according to claim 1,
wherein the external stimulus is heat stimulus.

6. The thermosetting resin composition according to claim 5,
wherein the functional group is deprotected by heat having a temperature of 140 to 200° C.

7. The thermosetting resin composition according to claim 1,
wherein the thermosetting resin composition contains a photo-acid-generating agent generating an acid by light stimulus, and
the external stimulus is the light stimulus.

8. The thermosetting resin composition according to claim 1,
wherein the thermosetting resin composition contains an ester exchange catalyst.

9. (canceled)

10. The thermosetting resin composition according to claim 1,
wherein the thermosetting resin composition contains a carboxylic anhydride or a carboxylic acid as a curing agent reacting with the epoxy compound to form the ester bond.

11. An electronic part comprising the thermosetting resin composition according to claim 1 as a mold sealant.

12. An electric machine coil insulation-treated using the thermosetting resin composition according to claim 1.

13. An electric machine comprising the electric machine coil according to claim 12.

14. A cable covered with the thermosetting resin composition according to claim 1.
